(19) United States
(12) Patent Application Publication
(10) Pub. No.: US 2016/0164249 A1
(43) Pub. Date: Jun. 9, 2016

(54) SEMICONDUCTOR LASER DIODE AND LASER ARRAY IMPLEMENTING THE SAME

(71) Applicant: Sumitomo Electric Industries, Ltd., Osaka-shi (JP)

(72) Inventor: Toshimitsu KANEKO, Yokohama-shi (JP)

(21) Appl. No.: 14/959,782

(22) Filed: Dec. 4, 2015

(30) Foreign Application Priority Data
Dec. 4, 2014 (JP) 2014-245704

(51) Int. Cl. H01S 5/026; H01S 5/12; H01S 5/32

(52) U.S. Cl. CPC H01S 5/026; H01S 5/3219; H01S 5/1228

(57) ABSTRACT

A semiconductor laser diode (LD) is disclosed. The LD provides a sampled grating distributed feedback (SG-DFB region) region and a distributed feedback (DFB) region accompanied with a region to shift the phase of light between two regions. Because the coupling coefficient κ for the light forwarding the facet of the SG-DFB region is lowered, while, the coupling coefficient for the light forwarding the facet of the DFB region is kept in high, the optical output power extracted from the facet of the SG-DFB region is enhanced.

### BACKGROUND OF THE INVENTION

1. Field of the Invention

The present invention relates to a semiconductor laser diode (LD) and a laser array implementing the LD.

2. Background Arts

A Japanese Patent Application laid open No. H05-029703A has disclosed a semiconductor laser diode with a type of the distributed feedback (DFB). A DFB-LD often provides a phase shift region in a center of a diffraction grating in order to stabilize the laser emission. The phase shift region shifts the phase corrugations constituting the diffraction grating by λ/4. FIG. 10 shows the electric field distribution of the light within a conventional DFB-LD. In FIG. 10, a behavior G11 shows the distribution of the forward light advancing from the right to the left, and another behavior G12 shows the distribution of the backward light advancing from the left toward the right. Because of the existence of the phase shift region in a center of the laser cavity, the forward light and the backward light are output from respective facets, 81A and 81B, by an even magnitude. Thus, a conventional DFB-LD may emit light with a single wavelength but the optical power output therefrom is evenly divided into respective facets, 81A and 81B, which means that an available optical power is limited.

### SUMMARY OF THE INVENTION

An aspect of the present application relates to a semiconductor laser diode (LD), in particular, to an LD able to extract an optical signal with a narrowed linewidth but large power. The LD of the invention comprises a first region and a second region optically coupled to each other. The first region provides a grating layer that includes discretely formed corrugated regions each separated by respective species and having refractive index different from materials surrounding the corrugations. The second region also provides a grating layer but including continuously formed corrugations whose refractive index is also different from refractive index of materials surrounding the corrugations.

### BRIEF DESCRIPTION OF THE DRAWINGS

The foregoing and other purposes, aspects and advantages will be better understood from the following detailed description of a preferred embodiment of the invention with reference to the drawings, in which:

FIG. 1A shows a cross section of a semiconductor laser diode (LD) according to an embodiment of the present invention, where FIG. 1A is taken perpendicular to the optical axis of the LD, and FIG. 1B shows another cross section of the LD taken along the optical axis thereof;

FIG. 2 shows a reflection spectrum attributed to the second region of the LD;

FIG. 3A shows a gain spectrum and a reflection spectrum of the LD, and FIG. 3B

FIG. 4 shows an oscillation spectrum of the LD when the first region provides a phase shifting;

FIG. 5 shows electrical field distribution of light in the laser cavity of the LD;

FIG. 6 shows across section of another LD according to the second embodiment of the present invention, where the cross section is taken along the optical axis;

FIG. 7 shows a cross section of still another LD according to the third embodiment of the present invention, where the cross section is taken along the optical axis of the LD;

FIG. 8 schematically shows a laser apparatus containing an arrayed laser according to the fourth embodiment of the present application;

FIG. 9 shows a gain spectrum and a reflection spectrum according to an example comparable to the present invention; and

FIG. 10 shows electric field distribution of light in the cavity according to the comparable example.

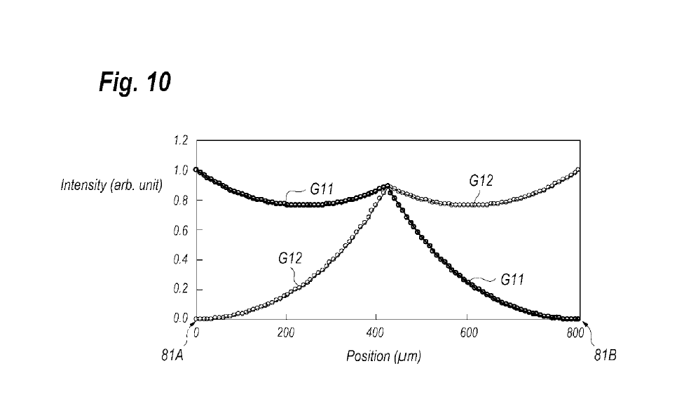

### DESCRIPTION OF EMBODIMENTS

Next, some embodiments according to the present invention will be described as referring to accompanying drawings. In the description of the drawings, numerals or symbols same with or similar to each other will refer to elements same with or similar to each other without duplicating explanations.

### First Embodiment

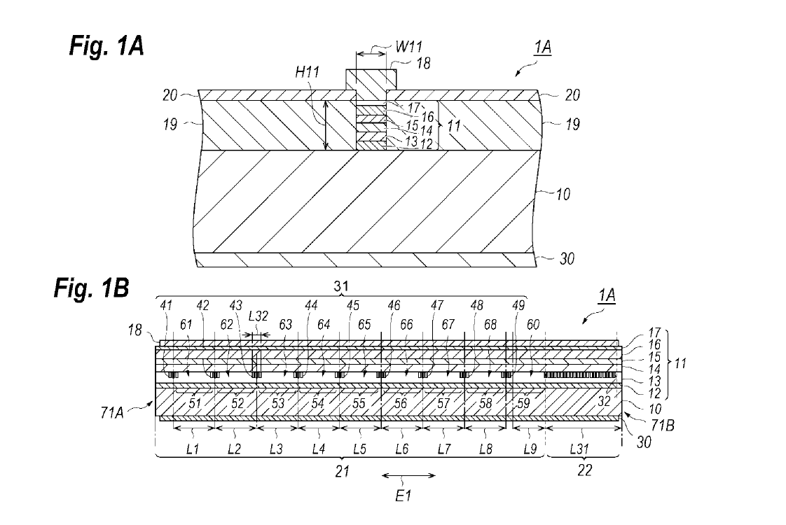

FIG. 1A shows a cross section of a semiconductor laser (LD) perpendicular to an optical axis of the LD, and FIG. 1B shows another cross section taken along the optical axis.

The LD 1A provides a semiconductor stack 11 formed on a primary surface of a semiconductor substrate 10. The semiconductor substrate 10 of the present embodiment may be made of n-type InP doped with silicon (Si) by a concentration of 5×10¹⁸ cm⁻³. The semiconductor stack 11 stacks a lower cladding layer 12, a grating layer 13, a burying layer 14, a waveguide layer 15, an upper cladding layer 16, and a contact layer 17 in this order on the semiconductor substrate 10. The semiconductor stack 11 provides a top electrode 18 on a top surface thereof; while, the semiconductor substrate 10 provides a back electrode 30 in a back surface thereof. The semiconductor stack is formed in a mesa, and the mesa is embedded by a semi-insulating layer 19. Provided on the semi-insulating layer 19 is an insulating layer 20. The mesa has a height H11 of, for instance, 1.5 μm and a width W11 of, for instance, 1.5 μm.

The lower cladding layer 12 may be made of n-type InP, which is epitaxially grown on a primary surface of the semiconductor substrate 10 and doped with silicon (Si) by a concentration of 1×10¹⁸ cm⁻³. The molecular beam epitaxy (MBE) and/or the metal organized chemical vapor deposition (MOCVD) may grow the lower cladding layer 12. The lower cladding layer 12 may have a thickness of the about 100 nm. The grating layer 13, which discretely includes optical gratings, 31 in the SG-DFB region 21 and continuously includes the optical grating 32 in the DFB region 22, may be made of n-type InP doped with silicon (Si) by a concentration of 1×10¹⁸ cm⁻³. The optical gratings, 31 and 32, may be made of n-type GaInAsP with a composition of Ga_{0.22}In_{0.78}As_{0.47}P_{0.53} also doped with silicon (Si) by a concentration of 1×10¹⁸ cm⁻³. The corrugations have a thickness of 60 nm. Because discretely formed regions, 41 to 49, in the optical grating 31 and another optical grating 32 including a continuously formed grating are formed by etching the layer made of GaInAsP with the surface thereof in a corrugated shape, these regions are sometimes called as the corrugated regions. Provided on the optical gratings, 31 and 32, and the grating layer 13 is a burying layer 14 made of InP doped with silicon (Si) by a concentration of 1×10¹⁸ cm⁻³. The burying layer 14 in a top surface thereof may be formed in flat by burying the discretely formed optical gratings 31 in the SG-DFB region 21 and continuously formed optical grating 13 in the DFB region 22. The optical gratings, 31 and 32, embedded by the grating layer 13 and the burying layer 14 may show a function of an optical grating because regions having refractive index different from that of materials burying the corrugations periodically appear. Because the corrugations in the SG-DFB 21 and the DFB 22 made of InGaAsP having refractive index are embedded by the grating layer 13 and the burying layer each made of InP having refractive index different from that of InGaAsP of the corrugations. Thus, the corrugations may form the optical gratings.

The waveguide layer 15 is grown on the burying layer 14. The waveguide layer 15 may be made of GaInAsP whose lattice constant substantially matches with that of InP and has a bandgap wavelength of 1.55 μm, which is measured by the photoluminescence spectrum thereof. The waveguide layer 15 may have a quantum well structure with respect to layers sandwiching the waveguide layer 15. The waveguide layer 15 of the present embodiment has a thickness of, for instance, 100 nm. The upper cladding layer 16, which is provided on the waveguide layer 15, may be made of p-type InP doped with zinc (Zn) by a concentration of 5×10¹⁷ cm⁻³ and have a thickness of 1.0 μm.

The semiconductor stack 11 may include a first region 21, which is generally called as a sampled-grating distributed feedback region (hereinafter simply denoted as SG-DFB region) having an optical gain, and a second region 22, which is called as a distributed feedback region (hereinafter simply denoted as DFB). These two regions, 21 and 22, are arranged along a direction E1 where the optical cavity of the semiconductor stack 11 extends. Although the former region 21, the SG-DFB region, inherently has the optical gain, the latter region 22, the DFB region, does not always have an optical gain. The LD 1A of the present embodiment provides the optical gain in the DFB region 22 and the waveguide layer 15 may operate as an active layer of the LD 1A.

The grating layer 13 in the SG-DFB region 21 provides a first optical grating 31 accompanied with corrugations, 41 to 49, while, the grating layer 13 in the DFB region 22 provides a second optical grating 32 also accompanied with corrugations but continuously distributed different from that 31 in the SG-DFB region 21. These optical gratings, 31 and 32, may be formed by the electron beam exposure, or the two-beam interference. A feature of the present embodiment is that the grating layer 13 in the DFB region 22 continuously provides the optical grating 32, but the grating layer 13 in the SG-DFB region 21 discretely provides the corrugated regions, 41 to 49, with intervals corresponding to respective spaces at which no corrugations are provided. Specifically, the optical grating 31 in the SG-DFB region 21 provides the grating layer 13 and a plurality of corrugated regions, 41 to 49, discretely disposed in the grating layer 13 along the direction E1 as interposing spaces, 61 to 65, without any corrugations. The LD 1A of the present embodiment provides, in the grating layer 13, nine (9) segments, 51 to 59, each including one corrugated region, 41 to 49, and one space. Such grating layer 13 with discretely disposed gratings may be formed by double exposure technique. Specifically, the two-beam interference may first form patterns for the corrugations continuously, then, an ordinary exposure is carried out only for areas corresponding to the spaces. The second exposure may remove the patterns for the corrugations. Thus, the corrugations discretely arranged along the cavity direction E1 interposing with spaces may be formed in the grating layer 13.

The grating layer 13 of the present embodiment provides a first phase adjusting region 60 between the DFB region 22 and the region 49 formed closest to the DFB region 22. The phase adjusting region 60 may be involved in the segment 59 closest to the DFB region 22.

The corrugations in the SG-DFB region 21 may have pitches of 230 to 250 nm. Specifically, the corrugations of the present embodiment have the pitch λ of 240 nm. Also, the corrugated regions, 41 to 49, may have lengths L31 of 10 to 30 multiplied by the pitch A. Thus, the corrugated regions, 41 to 49, of the present embodiment have the length L31 of 20λ; that is, the corrugated regions, 41 to 49, each include 20 corrugations. In such an arrangement of the corrugated regions, 41 to 49, the coupling co-efficient κ thereof becomes 150 cm⁻¹. Pitches or lengths, L1 to L8, between the corrugated regions, 41 to 49, may be optional in a range from 20 to 300 μm. The pitch of the present embodiment is 60.2 μm. A length L9 of the phase adjusting region 60, precisely, a length L9 of the space in the phase adjusting region 60 is also an optional but preferably shorter than ⅔ of the lengths, L1 to L8, between the corrugated regions, 41 to 49. The length L9 of the space longer than the lengths, L1 to L8, degrades the efficiency for extracting the light from the optical cavity.

The contact layer 17, which may be made of p-type Ga_{0.47}In_{0.53}As doped with zing (Zn) by a concentration of 5×10¹⁸ cm⁻³. The insulating layer 20, may be made of inorganic material such as silicon nitride (SiN) and/or silicon oxide (SiO₂), is a passivation layer to protect the epitaxially grown layers, 12 to 19, from atmosphere, especially, from moisture in the atmosphere. The top electrode 18, which is formed commonly on the SG-DFB region 21 and the DFB region 22, may include gold (Au). The LD 1A further provides two facets, 71A and 71B, in respective regions, 21 and 22. These facets, 71A and 71B, provide respective anti-reflection coatings attributed to reflectivity thereof less than, for instance, 1.0%. The AR coating in the facets, 71A and 71B, may enhance the extraction of the light out from the optical cavity of the LD 1A. The semi-insulating layer 19 may be made of InP doped with iron (Fe).

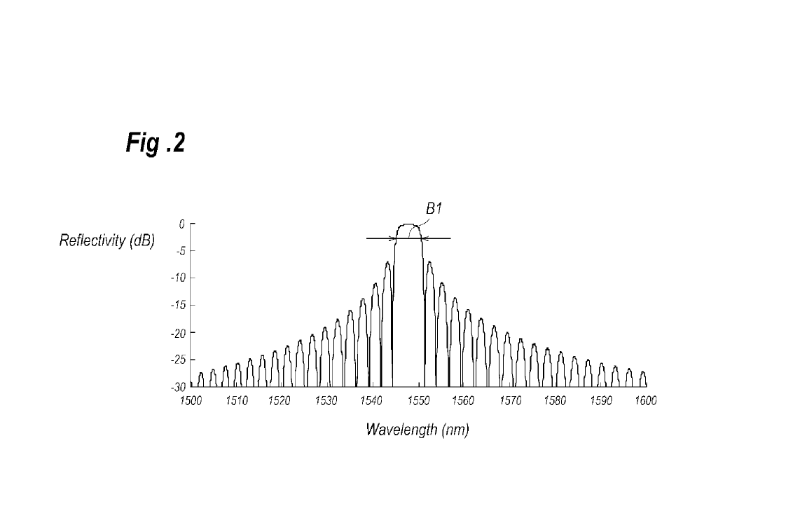

FIG. 2 shows an example of the reflection spectrum of the DFB region 22 according to the first embodiment. The reflection spectrum shown in FIG. 2 is for light entering the DFB region 22 externally. The pitch λ between the corrugations of the grating 13 in the DFB region 22 is same with the pitch λ between the corrugations in the SG-DFB region 21. That is, the pitch λ in the DFB region 22 may be 230 to 250 nm, and the first embodiment has the pitch of 240 nm. Also, the optical grating 32 in the DFB region 22 has a length L32 of 120 μm and the coupling co-efficient κ same with the coupling co-efficient κ in the SG-DFB region 21. For such physical arrangements of the corrugation, the DFB region 22 shows the reflectivity with a reflection bandwidth B1 of 5.5 nm, where the reflection bandwidth corresponds to a range where the reduction of the reflectivity is less than −3 dB with respect to the maximum reflectivity. Such bandwidth is often called as −3 dB bandwidth.

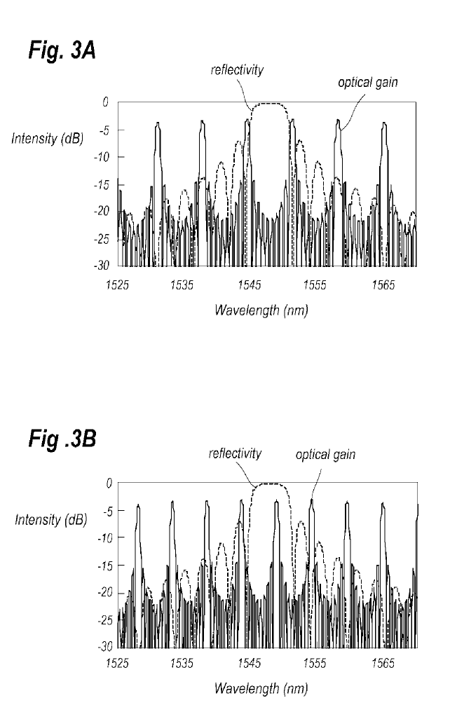

FIGS. 3A and 3B compare the optical gain with the reflectivity of the LD 1A of the first embodiment, where FIG. 3A shows a case an interval between the nearest gain peaks attributed to the SG-DFB region 21 is greater than the reflecting band width attributed to the DFB region 22, and FIG. 3B shows a case where an interval between the nearest gain peaks is narrower than, but greater than 80% of the reflection bandwidth. In the arrangement corresponding to FIG. 3A, the lengths, L1 to L8, between the corrugated regions, 41 to 49, are assumed to be 50 μm. The interval between the nearest gain peaks in FIG. 3A is 6.0 nm, which is wider than the reflection bandwidth of 5.5 nm; accordingly, the arrangement of FIG. 3A enables that only one gain peak exists within the reflection bandwidth. When the reflection bandwidth includes only one gain peaks, the LD 1A stably oscillates at the wavelength coinciding to that of the gain peak. On the other hand, when the reflection bandwidth includes two or more gain peaks, the laser oscillation becomes instable between respective gain peaks. In the first embodiment, adjusting the phase of the light in the phase adjusting regions, 61 to 68, in respective segments, 51 to 59, that is, adjusting the optical lengths of the spaces, 61 to 68, between the gratings, 41 to 49; the gain peak in the reflection bandwidth may be set closer to a center of the reflection bandwidth. The adjustment of the phase may be carried out by adjusting the optical lengths of the spaces, 61 to 68, and/or shifting the corrugations, in particular, shifting the phase of the corrugation, where the former is known as the equivalent phase shift and the latter is known as the physical phase shift.

For the case shown in FIG. 3B, where the reflection bandwidth includes two or more optical gain peaks, the interval between the optical gain peaks is 5.0 nm, which is narrower by 10% of the reflection bandwidth of 5.5 nm. That is, two gain peaks may exist within the reflection bandwidth. On the other hand, the arrangement of an LD corresponding to FIG. 3B may always set at least one gain peak within the reflection bandwidth. That is, even when one gain peak is set outside of the reflection bandwidth, another gain peak may be shifted within the reflection bandwidth by imparting the phase shift in the spaces, 61 to 69. Thus, the interval between the nearest gain peaks is preferably 10% narrower than the reflection bandwidth.

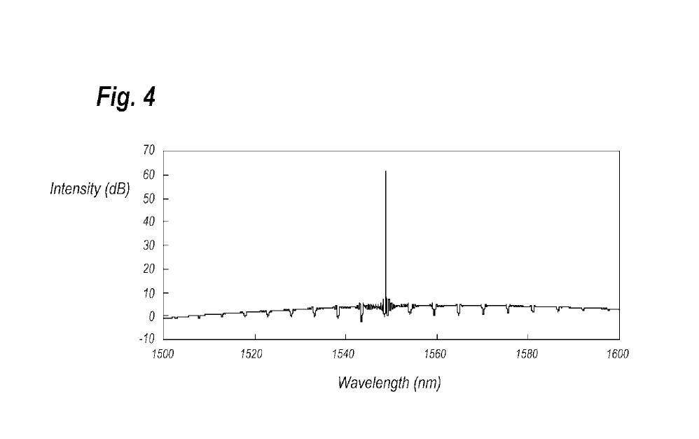

FIG. 4 shows an oscillation spectrum of the LD 1A when the phase adjusting region 60 is imparted by a phase shift of −0.4π (radian), specifically, the phase of the corrugations in the SG-DFB region 21 and that of the DFB region 22 are shifted by 0.4λ (nm) by the phase adjusting region 60 as a boundary, where λ(nm) is the pitch of the corrugations in respective regions, 21 and 22, which is the physical phase shift described above. As shown in FIG. 4, the LD 1A having such arrangements including the corrugated regions, 41 to 49, the spaces, 61 to 68, and the phase adjusting region 60, may oscillate at the wavelength around 1550 nm with extremely narrowed linewidth.

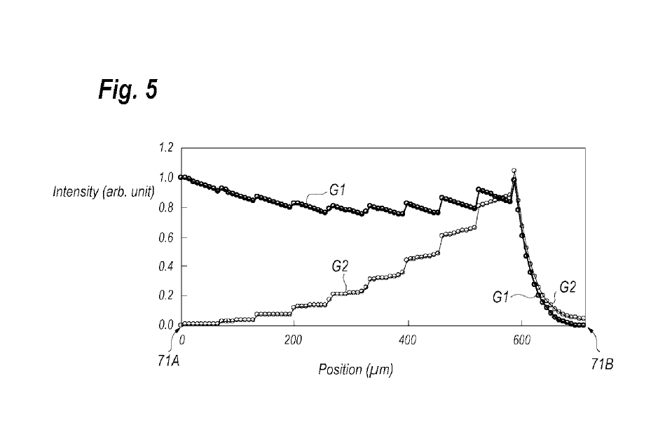

FIG. 5 calculates distributions of electric fields within the optical cavity of the LD 1A when the LD 1A emits the laser light shown in FIG. 4. The forward light G1 traveling from the right to the left is output from the facet 71A with substantial intensity but not output from the other facet 71B. The backward light G2 traveling from the left to the right is almost eliminated at the facet 71A and slightly left in the other facet 71B. The LD 1A shows a ratio of the optical power output from the facet 71A primarily due to the forward light against the optical power output from the other facet 71B due to the backward light is about 95:5.

According to the LD 1A of the embodiment, the reflection bandwidth attributed to the DFB region 22 may include only one gain peak attributed to the SG-DFB region 21 by adjusting the optical lengths of the spaces, 61 to 68, in the respective segments, 51 to 58. Because the coupling efficiency of the corrugated regions, 41 to 49, in the SG-DFB region 21 is smaller than that of the DFB region 22 due to the discrete arrangement thereof, the optical power output from the facet 71A in the side of the SG-DFB region 21 may be enhanced.

The LD 1A of the embodiment provides the optical grating 31 including the discretely formed corrugated regions, 41 to 49, in the SG-DFB region 21 each disposed along the cavity direction. The optical power extractable from the facet of the LD may depend on the coupling co-efficient κ multiplied with the length of the cavity L, namely, κL. The parameter κL, which corresponds to the reflectivity of the facet in an LD having a simple Fabry-Perot structure, determines the reflectivity of the facet; that is, when the κL becomes smaller, the reflectivity of the facet decreases, while, the reflectivity of the facet becomes larger as the κL becomes greater. For the LD 1A of the embodiment, because of the first region 21 has the SG-DFB structure, the parameter κL for the forward light G1 becomes smaller at the facet 71A compared with that at the opposite facet 71B, which results in the difference in the optical power for the forward light at the respective facets, 71A and 71B. That is, the forward light G1 shows the greater optical power only at the facet 71A. On the other hand, the parameter κL becomes large at the respective facets, 71A and 71B, for the backward light G2, that is, the backward light G2 perceives substantial reflectivity at the respective facets, 71A and 71B, which restricts the optical power due to the backward light extractable at the respective facets, 71A and 71B. Accordingly, the LD 1A of the embodiment may restrict the optical output thereof substantially in one of the facets 71A, and may enhance the optical power extracted therefrom. Moreover, because the SG-DFB region 21 restricts the number of corrugated regions, 41 to 49, that is, the SG-DFB region 21 provides the discretely distributed corrugated regions; the number of the corrugations may be suppressed which means that the process to from the corrugations may be stabilized.

A conventional LD with a type of the Fabry-Perot often provides one facet with high reflectivity and another facet with restricted reflectivity to increase the optical power extracted from the former facet, which is often called as the LR-HR structure. On the other hand, in a conventional DFB-LD having the continuous corrugations but a region in a center of the corrugations to shift a phase of light propagating along the corrugations by λ/4 is impossible to differ the reflectivity between the respective facets because the coupling coefficient κ of the optical waveguide becomes uniform as far as the DFB-LD is conventionally formed. One technique to differ the reflectivity between the facets is to move the region to shift the phase of the light by λ/4 from the center of the corrugations. However, such an arrangement of the region inevitably degrades the shape of the spectrum of the laser light output from the DFB-LD. Accordingly, the conventional DFB-LD is necessary to form the region to shift the phase of the light in the center of the corrugations, which automatically results in the optical output power evenly distributed in the respective facets. The LD 1A of the present embodiment has not the diffraction gratings uniformly distributed along the cavity as the conventional DFB-LD.

The structure of the corrugations in the respective regions, 21 and 22, may also bring an advantage in a linewidth of the light extracted from the LD 1A. Recent optical communication systems strongly request the extremely narrowed linewidth in the laser emission. The linewidth of the laser emission is reversely proportional to the number of photons in the cavity. Accordingly, a lengthened cavity is preferable in a point of the linewidth because the absolute number of the photon increases in such a lengthened cavity. However, the lengthened cavity is generally hard to be stably formed. As described, a DFB-LD generally shows a larger threshold current for a smaller coupling coefficient κ. On the other hand, it becomes hard to extract the optical output power for a greater coupling coefficient κ. That is, the coupling coefficient κ has an optimum condition, which means that the production of a DFB-LD is necessary to be precisely controlled. When the DFB-LD has a lengthened cavity, the process conditions are necessary to be strictly controlled. On the hand, the LD 1A of the embodiment, the light is not strongly confined within the cavity even when the cavity is lengthened, which means that the control of the process determining the coupling coefficient κ may be relaxed. Thus, the LD 1A of the embodiment may have a lengthened cavity which is preferable to narrow the linewidth of the laser emission.

The LD 1A of the embodiment is preferable to have the optical gain in the DFB region 22. The second region 22 of the DFB operates as a light reflector, which means that the waveguide in the second region 22 is unnecessary to have an optical gain but preferable to show smaller optical loss. One technique to realize such a function is that the waveguide in the SG-DFB region 21 and that in the DFB region 22 are made of same material and the optical gain in the DFB regions 22 may be realized through a common electrode. Two waveguides may be made of respective materials, but, this arrangement must accompany with a complex process. The waveguide in the DFB region 22 having the optical gain in addition to the waveguide in the SG-DFB region 21 may enhance the optical power output from the LD 1A.

The interval between the nearest gain peaks attributed to the SG-DFB region 21 is preferably wider than the reflection bandwidth attributed to the DFB region 22. The LD 1A having such a structure may oscillate at the wavelength where the one gain peak of the SG-DFB region 21 is within the reflection bandwidth of the DFB region 22. Accordingly, in order to oscillate stably at the one wavelength, one gain peak of the SG-DFB region 21 always exists within the reflection bandwidth of the DFB region 22. Thus, the interval between the nearest gain peaks is preferably wider than the reflection bandwidth.

In an alternative, the LD 1A of the present embodiment may have an arrangement where the interval between the nearest gain peaks attributed to the SG-DFB region 21 is narrower than, but wider than 80% of, the reflection bandwidth attributed to the DFB region 22. Too wider interval between the gain peaks sometimes causes a condition where no gain peak exists within the reflection bandwidth. The center wavelength of the reflection bandwidth of the DFB region 22 coincides with the Bragg wavelength of the continuous corrugations in the DFB region 22, which is determined by the pitch of the corrugations and shows substantially no variation depending on the process to form the corrugation. On the other hand, the wavelengths of the gain peaks attributed to the SG-DFB region 21 depend on the optical lengths between the respective corrugated regions, that is, the optical lengths of the spaces. An optical length of a material depends not only on the physical length thereof but also on equivalent refractive index thereof, which is slightly scattered compared with those determined by the process. Accordingly, the LD 1A preferably has the interval between the gain peaks narrower than, but wider than 80% of, the reflection bandwidth such that the stable laser emission is output from the LD 1A even when the wavelengths of the gain peaks are varied. In such an arrangement, two gain peaks possibly exist within the reflection bandwidth; but the LD 1A may oscillate at one wavelength except for a condition where the reflectivity at the wavelengths corresponding to the gain peaks coincide to each other.

The LD 1A preferably provides the region 60 to shift the phase of the corrugations between the optical grating 13 in the DFB region 22 and that 31 including the corrugated regions, 41 to 49, in the SG-DFB region 21, which is the physical phase shift, or the region 60 has an optical length corresponding to the shift of the light by a predetermined amount. The region 60 may stabilize the laser oscillation, and the LD 1A resultantly shows a low threshold current.

The LD 1A may further provide the spaces 61 to 68 between the discretely formed corrugations, 41 to 49. Adjusting the optical lengths of the spaces, 61 to 68, the gain peaks attributed to the SG-DFB region 21 may be set within the reflection bandwidth, preferably in a center of the reflection bandwidth.

### Second Embodiment

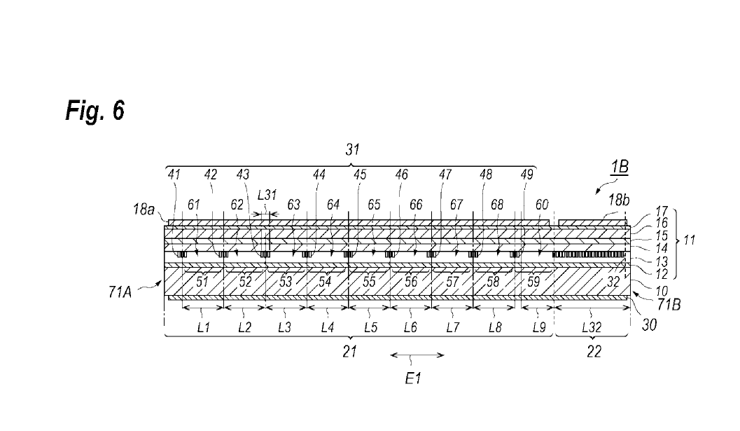

FIG. 6 schematically shows a cross section of another LD 1B according to the second embodiment of the present application, which is taken along the cavity direction. The LD 1B has a feature, compared with the aforementioned embodiment 1A, that the LD 1B has two top electrodes each provided in the SG-DFB region 21 and the DFB region 22. The DFB region 22 shows an optical gain similar to the aforementioned embodiment.

Because the LD 1B of the second embodiment provides the top electrode 18a in the SG-DFB region 21 and the other top electrode 18b in the DFB region 22, which means that biases for respective regions, 21 and 22, through the top electrodes, 18a and 18b, may be optimized for the regions, 21 and 22, independently. For instance, because the DFB region 22 inherently shows lessor conversion efficiency from the injection of carriers to the generation of photons compared with the SG-DFB region 21; total conversion efficiency from the carrier injection to the photon generation may be enhanced by suppressing the bias current in the DFB region 22 while increasing the bias current in the SG-DFB region 21.

The top electrode 18a in the SG-DFB region 21 may be further divided into two parts, one is provided on the region 60 and the other is formed on rest of the spaces, 61 to 68. The electrode on the region 60 may precisely align the phase of the light propagating therethrough, that is, the electrode localized in the region 60 may precisely adjust the optical length of the region 60.

### Third Embodiment

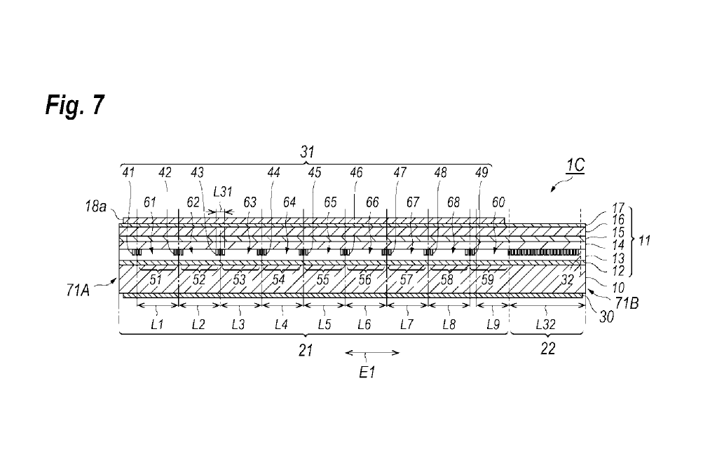

FIG. 7 schematically shows a cross section of still another LD 1C taken along the cavity direction thereof. The LD 1C shown in FIG. 7 provides another top electrode, that is, the LD 1C provides the top electrode 18a only in the SG-DFB region 21, and the DFB region 22 provides no top electrode. Accordingly, the DFB region 22 shows no optical gain, which means that the DFB region 22, or the second region 22, operates merely as a distributed Bragg reflector (DBR). The second region 22 shows a reflection spectrum such as those shown in FIG. 2 by which the SG-DFB region 21 may emit light with the single wavelength.

### Fourth Embodiment

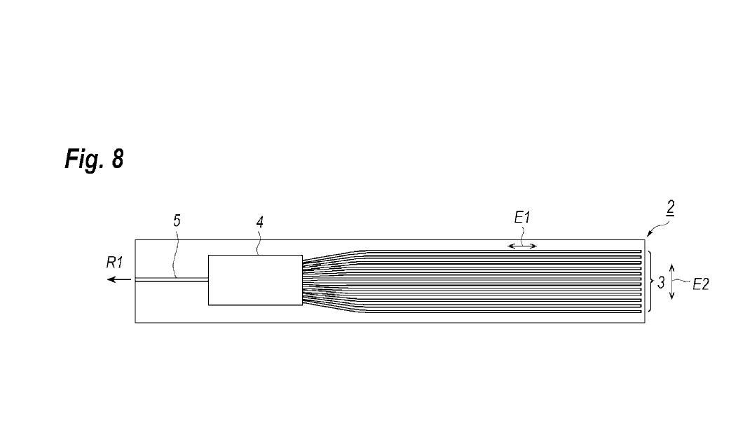

FIG. 8 is a plan view schematically illustrating an optical source including an arrayed LD. The optical source 2 includes an arrayed LD 3, an optical multiplexer 4, and an optical waveguide 5. The arrayed LD 3 is coupled with the optical multiplexer 4, and also with the optical waveguide 5 through the optical multiplexer 4. The arrayed LD 3, as shown in FIG. 8, provides LDs each disposed along a direction E2, which is perpendicular to the cavity direction E1. For instance, the arrayed LD 3 may include twelve (12) LDs each having the structure same with those of the LD 1A of the first embodiment. Respective LDs in the arrayed LD 3 optically couple with the optical multiplexer 4 by respective aligning facets, which are corresponding to the facet 71A in FIG. 1B where the optical outputs are extracted therefrom. The optical multiplexer 4 may be a type of 12:1 multi-mode interference (MMI) coupler. The optical waveguide 5 may include a semiconductor optical amplifier (SOA).

The arrayed LD 3 may output light with the single wavelength and enhanced power when one of the LDs 1A corresponding to the single wavelength is activated. Also, the arrayed LD 3 may output light with another single wavelength and enhanced power when another of the LDs 1A corresponding to the other single wavelength is activated. The light R1 with an enhanced power may be output from the optical waveguide 5 through the optical multiplexer 4. When the optical waveguide 5 provides an SOA, the optical source 2 may output light R1 with further enhanced power but with the single wavelength from the optical waveguide 5. Thus, according to the arrayed LD 3 that has a plurality LDs each attributed to respective pitches of the corrugations in the gratings, the arrayed LD 3 may expand a wavelength bandwidth within which the arrayed LD 3 may output the laser light depending on the number of LDs 1A.

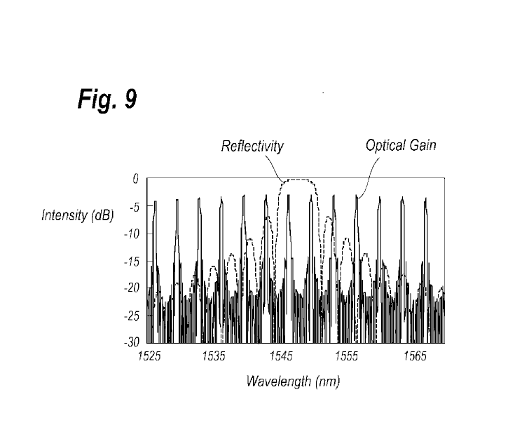

FIG. 9 shows the reflectivity and the optical gain according to an example comparable to the LD 1A of the present invention. As shown in FIG. 9, the interval between the nearest gain peaks is narrower than 80% of the reflection bandwidth in the reflectivity. The LD provides the spaces, L1 to L8, with the physical lengths thereof to be around 65 μm, that is, the pitch between the corrugated regions is shorter than the pitch of the LD 1A of the embodiment, which is around 60 μm. The arrangement of the conventional LD is same with those of the embodiment 1A except for the pitch between the gratings described above. In FIG. 9, the interval between the nearest gain peaks is narrower than the reflection bandwidth, which is 5.5 nm in the present embodiment. Accordingly, the reflection bandwidth may occasionally include two or more gain peaks. Then, the DFB region 22 may substantially reflect at two wavelengths, which results in an unstable laser oscillation of the LD 1A.

In the foregoing detailed description, the LD of the present invention has been described as referring to specific exemplary embodiments thereof. It will, however, be evident that various modifications and changes may be made thereto without departing from the broader spirit and scope of the present invention. The present specification and figures are accordingly to be regarded as illustrative rather than restrictive.

I claim:

1. A semiconductor laser diode (LD), comprising:
a first region provided on a semiconductor substrate, the first region having a grating layer including discretely formed corrugated regions each including corrugations and being separated by respective spaces; and
a second region provided on the semiconductor substrate, the second region being optical coupled with the first region and having the grating layer including continuously formed corrugations,
wherein the corrugations in the first region and the second region have refractive index different from indices of materials surrounding the corrugations.

2. The LD of claim 1,
wherein the first region shows a plurality of gain peaks and the second region shows a reflection bandwidth, and
wherein the gain peaks have an interval between the nearest neighbor gain peaks wider than the reflection bandwidth of the second region.

3. The LD of claim 1,
wherein the first region shows a plurality of gain peaks and the second region shows a reflection bandwidth, and
wherein the gain peaks have an interval between the nearest neighbor gain peaks wider than 80% of the reflection bandwidth and narrower than the reflection bandwidth.

4. The LD of claim 1,
further includes a region between one of the corrugated regions closest to the second region and the second region, the region having no corrugations.

5. The LD of claim 4,
wherein the region has an optical length different from optical lengths of the spaces in the first region.

6. The LD of claim 4,
wherein the corrugated regions in the first region include corrugations having a pitch different from a pitch of the corrugations continuously formed in the second region.

7. The LD of claim 6,
wherein the pitch of the corrugations in the first region is different from the pitch of the corrugations in the second region by λ/4, where λ is a wavelength of light emitted from the LD.

8. The LD of claim 6,
wherein the pitch of the corrugations in the first region is different from the pitch of the corrugations in the second region by −0.4π radian.

9. The LD of claim 1,
further including a top electrode extending from the first region to the second region,
wherein the second region has an optical gain.

10. The LD of claim 9,
wherein the top electrode is divided into two electrodes, one of the top electrodes being disposed in the first region and another of the top electrodes being disposed in the second region.

11. The LD of claim 1,
further including a top electrode provided only in the first region,
wherein the second region has no optical gain.

12. The LD of claim 1,
further including a lower cladding layer, a waveguide layer, and an upper cladding layer,
wherein the lower cladding layer, the waveguide layer, and the upper cladding layer extend in the first region and the second region, the grating layer in the first region and the grating layer in the second region being sandwiched by the lower cladding layer and the waveguide layer.

13. The LD of claim 12,
wherein the semiconductor substrate, the lower cladding layer, the grating layer, and the upper cladding layer are made of InP, and the discretely formed corrugated regions in the grating layer in the first region and the continuously formed corrugated regions in the grating layer in the second region are made of GaInAsP.

14. The LD of claim 12,
wherein the waveguide layer is made of GaInAsP.

15. The LD of claim 1,
wherein the first region provides a sampled-grating distributed feedback (SG-DFB) region comprised of the lower cladding layer, the grating layer including the discretely formed corrugated regions, the waveguide layer and the upper cladding layer; and
wherein the second region provides a distributed feedback (DFB) region comprised of the lower cladding layer, the grating layer including the continuously formed corrugations, the waveguide layer, and the upper cladding layer.
